(19) United States
(12) Patent Application Publication
(10) Pub. No.: US 2010/0015807 A1
(43) Pub. Date: Jan. 21, 2010

(54) Chemical Mechanical Polishing Composition for Copper Comprising Zeolite

(75) Inventors: Seok-Ju Kim, Gongju-si (KR); Hyu-Bum Park, Yeongi-gun (KR); Eun-Il Jeong, Daejeon (KR)

Correspondence Address: THE WEBB LAW FIRM, P.C., 700 KOPPERS BUILDING, 436 SEVENTH AVENUE, PITTSBURGH, PA, 15219, US

(73) Assignee: TECHNO SEMICHEM CO., LTD., Seongnam-si (KR)

(21) Appl. No.: 12/519,940

(22) PCT Filed: Dec. 20, 2007
(86) PCT No.: PCT/KR2007/006706

§ 371 Date: Jun. 18, 2009

(30) Foreign Application Priority Data
Dec. 22, 2006 (KR) 10-2006-0133143
Jul. 26, 2007 (KR) 10-2007-0074841

(51) Int. Cl. H01L 21/302

(52) U.S. Cl. 438/693; 252/79.1; 252/79.5; 257/E21.23

(57) ABSTRACT

The present invention relates to a CMP slurry composition for polishing a copper film in a semiconductor device fabricating process. The CMP composition for polishing a substrate comprising copper comprises zeolite, an oxidizer and a complexing agent and a content of the complexing agent is 0.01˜0.8 weight % with respect to an entire weight of the polishing composition.

### TECHNICAL ART

The present invention relates to a chemical mechanical polishing slurry composition for polishing a copper film in a semiconductor device fabricating process.

### BACKGROUND ART

Recently, in a semiconductor device fabricating process, a size of a wafer has been increased, which now has a diameter of 300 mm, and the number of metal wiring layers has been also increased due to high integration for the high-functioning semiconductor device, and thus the reliance on a planarization technology has been grown due to the application of a rigid DOF (Depth of focus) and a precise design rule. The global planarization of ILD (interlayer dielectric) and PMD (pre-metal dielectric) layers has already become an essential process.

Further, in order to solve a problem that wiring resistance is increased due to a fine wiring pattern on the device, copper has been used as a wiring material, instead of tungsten or aluminum. After a copper chip using a Damascene process had been published by IBM on 1997, a process for fabricating the copper chip has been actively developed. Since an etching process using plasma can not be performed when copper is used as a metal wiring, it is known that the Damascene process can not be performed without a chemical mechanical polishing (CMP) process. Therefore, according as the use of copper wiring in the semiconductor device is grown, the importance of copper polishing slurry is also increased.

Generally, the copper polishing process is performed as two step process, first bulk Cu polishing and second barrier polishing. In the bulk copper polishing, the copper is rapidly removed by using slurry which has a high removal rate for the copper and high selectivity of copper layer with respect to barrier layer, and then the polishing operation is stopped at a tantalum-based barrier layer.

In other words, as the bulk copper polishing slurry, the slurry having a high removal rate for the copper and a high selectivity of a copper layer with respect to a barrier layer has been developed. There has been disclosed a conventional bulk copper polishing slurry containing an abrasive, an oxidizer and a complexing agent which is bound with copper ions so as to improve the removal rate for the copper layer. For example, the bulk copper polishing slurry containing an organic acid-based compound as the complexing agent has been disclosed in U.S. Pat. No. 6,593,239 in which a polishing composition containing an abrasive, an oxidizer of 0.3˜15.0 weight %, a complexing agent of 1˜3 weight % and a film forming agent of 0.08˜1 weight % is described. However, since the polishing slurry composition contains the complexing agent more than 1 weight %, it is difficult to control dishing and corrosion (or etching) of the copper layer.

As described above, the conventional bulk copper polishing slurry uses the complexing agent, which can be bound with the copper ions, in order to increase the removal rate for the copper layer. However, since the content of the complexing agent is too high, there is a strong probability that the dishing or other defect may be occurred due to increase in a copper etch rate, and further, in case that the content of the complexing agent is too small, the removal rate becomes low.

Meanwhile, in Korea Patent No. 0165145, there is disclosed a copper polishing slurry composition containing glycine. The copper polishing slurry composition have a function forming an oxide film on a surface of the copper layer so as to restrict the etching of the copper layer. In the copper polishing slurry composition, since a weight ratio of the oxidizer/organic acid is maintained at 20 or more and the pH is maintained in a basic pH region not a neutral pH region, it is apprehended that the reproducibility of the polishing performance will be deteriorated due to decomposition of hydrogen peroxide in the basic pH region. Further, in case that the copper polishing slurry composition is used in the neutral pH region, the polishing performance for the copper layer is also deteriorated.

### DISCLOSURE

[Technical Problem] It is an object of the present invention to provide a bulk copper CMP composition which has a high removal rate for the copper layer and a high selectivity of a copper layer with respect to a barrier layer as well as a minimized content of the complexing agent.

It is another object of the present invention to provide a bulk copper CMP composition which can control the dishing and corrosion (or etching) of the copper layer.

[Technical Solution]

The inventors found a fact that, if a polishing slurry composition comprises zeolite, the polishing slurry composition can have a high removal rate for the copper layer and a high selectivity of a copper layer with respect to a barrier layer using a small amount of complexing agent.

The present invention relates to a bulk copper CMP composition for polishing of a substrate containing copper layer is formed in a semiconductor fabricating process, which is characterized that zeolite is used to absorb the copper ions and realize mechanical polishing mechanism, more particularly, to a bulk copper CMP composition which comprises zeolite, a complexing agent and an oxidizer wherein the content of the complexing agent is 0.01˜0.8 weight %.

The zeolite is a porous material in which nano-pores having a desired size are regularly arranged. The zeolite can be classified into an aluminosilicate, an aluminophosphate (AlPO₄), a silicoaluminophophate (SAPO) zeolite, a metal aluminophosphate (MeAPO) and a metallosilicate zeolite according to their composition.

The aluminosilicate-based zeolite can be expressed by a formula as follows:

M_{2/n}O.xAl₂O₃.ySiO₂.zH₂O

wherein M is a positive ion having an atomic value of n, z is a molecular number of water of crystallization, and a ratio of y/x is changed according to a crystal structure and typically has a value of 1˜100.

The zeolite generally has pores of 5˜20 Å and a size of an entrance of the pores is 3˜13 Å. In general, the zeolite has a void volume of 15˜50%, a wide surface area of 200 m²/g or more, a low Mohr hardness of 2˜5 and a low density of 2˜3 g/cm³.

Since the zeolite has the internal pores having a large volume which receives a compound therein, when it is used in the CMP, the zeolite can comprise an useful compound before the CMP and also absorb and remove the copper ions after the CMP of the copper layer, thereby having an excellent polishing property. Further, since the zeolite has the lower hardness and density than the conventional inorganic particles, it is possible to restrict scratches generation during the polishing process.

Further, due to the properties of the zeolite as described above, since it is possible to reduce the content of the complexing agent contained in the conventional copper polishing slurry composition, it is possible to provide a high removal rate for the copper and a high selectivity of a copper layer with respect to a barrier layer using a small amount of the complexing agent and also reduce occurrence of the dishing and corrosion

Hereinafter, the present invention is described in detail.

The present invention relates to a bulk copper polishing composition comprising zeolite, a complexing agent and an oxidizer, wherein a content of the complexing agent is 0.01˜0.8 weight % with respect to an entire weight of the composition. And, the polishing composition according to the present invention can further comprises one or more additives selected from an anticorrosive agent, a surfactant, aminoalcohol, a water-soluble polymer and an anti-foaming agent.

Preferably, the zeolite contained in the bulk copper polishing composition according to the present invention is prepared so as to have a secondary average particle size of 10˜1000 nm in a slurry solution, more preferably, 50˜300 nm. If the particle size is more than 1000 nm, there are some disadvantages that dispersion stability is lowered due to precipitation and the scratch is generated by large particles, and if the particle size is less than 10 nm, it is difficult to prepare it and also the removal rate is lowered. The zeolite having the average particle size within the extent may be prepared by pulverizing the zeolite having a large particle size or directly synthesizing the zeolite having the average particle size into the nano-sized one. The synthesizing process may be achieved by heating reactants at a high temperature in a basic solution or performing hydrothermal synthesis.

In case of pulverizing the zeolite, it is preferable that the pulverized zeolite is prepared to have an average particle size within the above-mentioned extent and also particle distribution is formed to be narrow and uniform in order to obtain the dispersion stability and the removal rate required in the copper polishing process and reduce a μ-scratch generation. In the pulverizing of the zeolite, the zeolite may be mixed with a medium like water and then minutely pulverized by milling, hi-mixing or fluid impacting, and the dispersion solution is distributed.

In the present invention, the method of pulverizing the zeolite includes the milling, hi-mixing and fluid impacting methods. In the milling method, the zeolite is mixed with beads and then stirred at a high speed by using a bead mill, a Dynomill, a ballmill and an attrition mill. In the hi-mixing method, the fluid is rotated at a high speed by using a rotor and struck against a stator so as to produce friction. Further, the fluid impacting method is an oppositely impacting method. During the pulverizing process of the zeolite, native crystallinity of the zeolite may be reduced or lost. However, such the pulverized zeolite can be used in the present invention.

There are various kinds of zeolites according to their compositions and structures, and all materials having internal pores can be used in the present invention without limitation of their compositions and structures, if they are synthesized or pulverized to have a particle size within the above-mentioned extent. In the present invention, the aluminosilicate zeolite is used. The aluminosilicate zeolite is a porous composite oxide, which has a regular tetrahedral coordination structure formed by silicon and aluminum atoms and oxygen atoms as a basic structure, can be variously classified according to its structure. The zeolite Al₂O₃/SiO₂ can have a different polishing property and a different selectivity according to its content ratio and structure. It is preferable that the zeolite selected from an X type, a Y type, a 4A type and a ZSM-5 type is used.

Preferably, a content of the zeolite contained in the bulk copper polishing composition according to the present invention is 0.1˜7 weight %, more preferably, 0.3˜5 weight %. If the content of the zeolite is less than 0.1 weight %, the absorbing ability of copper ions is relatively deteriorated, and also it can hardly make a contribution to the mechanical polishing mechanism, and if the content of the zeolite is more than 7 weight %, the removal rate of the barrier metal layer is increased and the dispersion stability of the slurry is deteriorated.

The complexing agent contained in the bulk copper polishing composition according to the present invention may be an organic acid or an amino acid, and the complexing agent includes citric acid, malonic acid, adipic acid, succinic acid, oxalic acid, gluconic acid, tartaric acid, malic acid, diethylmalonic acid, acetic acid, mercaptosuccinic acid, benzenetetracarboxylic acid, quinolinic acid, glycine, alanine, valine, aspartic acid, glutamic acid, arginine and the like. It is preferable that a content of the complexing agent is 0.01˜0.8 weight %, more preferably, 0.05˜0.5 weight %. If the content of the complexing agent is less than 0.01 weight %, the removal rate of copper is so low and thus it can not be used substantially in the industrial field, and if the content of the complexing agent is more than 0.8 weight %, the removal rate of copper is increased, but the etch rate is also increased and there is a possibility that the dishing or corrosion of the copper layer is occurred. In case that the citric acid is used as the complexing agent, it is possible to control the removal rate by changing the content of the citric acid.

The polishing composition according to the present invention can be used in the acid, neutral or basic pH region, e.g., in an extent of pH 3˜12. In order to control the pH, KOH, ammonia, tetramethylammonium hydroxide, morpholine and the like and a mixture thereof are used as a basic material, and an inorganic acid such as nitric acid, phosphoric acid, sulphuric acid, hydrochloric acid and the like is used as an acid material. The acid pH region is preferably pH of 3˜6.5, more preferably, pH of 3˜6, and the neutral pH region is preferably pH of 6.5˜8.5, more preferably, 7˜8, and the basic pH region is preferably pH of 8.5˜12. Preferably, one or more selected from potassium hydroxide, nitric acid, tetramethylammonium hydroxide, ammonium hydroxide (NH₄OH), and morpholine are used as a pH controlling agent. If the pH is higher than the above-mentioned extent, the dispersion stability of zeolite is deteriorated, and large-sized particles are generated, and thus it can be used as polishing slurry, and if the pH is lower than the above-mentioned extent, corrosiveness is increased.

The oxidizer contained in the polishing slurry composition according to the present invention functions to oxidize a surface of the copper layer. It is preferable that a content of the oxidizer is 0.01˜15 weight % with respect to an entire weight of the composition. If the content is less than 0.01 weight %, oxidizing power is deteriorated and thus the removal rate is lowered, and if the content is more than 15 weight %, the corrosiveness is increased. The oxidizer includes a compound containing one or more peroxy group, a compound containing an element in the highest oxidation state and a mixture thereof. The compound containing one or more peroxy group includes an addition product of hydrogen peroxide such as hydrogen peroxide, urea hydrogen peroxide and percarbonate, organic peroxide such as benzoylperoxide, peracetic acid and di-t-butylperoxide, persulphate(monopersulphate, dipersulphate), sodium peroxide, and a mixture thereof. The compound containing an element in the highest oxidation state includes periodate, perborate, permanganate and the like, and a non-per compound can be used. The non-per compound includes bromates, chromates, iodates, iodic acids and cerium (IV) compounds such as cerium (IV) ammonium nitrate, and a compound like ferric nitrate also can be used as the oxidizer.

According to the polishing composition of the present invention, it is preferable that the different kinds of oxidizers are used in each of the acid, neutral and basic pH regions in order to improve the removal rate and obtain their stability, and it is also preferable that the content of the oxidizer is different in each of the acid (pH 3˜6.5), neutral (pH 6.5˜8.5) and basic pH (pH 8.5˜12) regions. Hydrogen peroxide is preferably used as the oxidizer in the acid or neutral pH region, and the content of the hydrogen peroxide in the acid pH region is 1˜12 weight % with respect to an entire weight of the polishing composition, more preferably, 3˜10 weight %. If the content of the hydrogen peroxide in the acid pH region is less than 1 weight %, the removal rate of copper is lowered and the scratch is generated on a surface, and if the content of the hydrogen peroxide in the acid pH region is more than 12 weight %, since a copper oxide layer becomes strong, it is difficult to remove the copper layer and thus the removal rate of copper is lowered. Further, it is preferable that the content of the hydrogen peroxide in the neutral pH region is 0.1˜3 weight %, more preferably, 0.1˜2 weight % and most preferably, 0.1˜1 weight %. If the content of the oxidizer is less than 0.1 weight %, the removal rate of copper is lowered due to the low oxidizing power, and if the content of the oxidizer is more than 3 weight %, the corrosiveness is increased and thus the copper surface becomes non-uniform. It is preferable that persulphate is used as the oxidizer in the basic pH region, and the content of persulphate is 0.05˜5 weight %, more preferably, 0.5˜3 weight %. If the content of a persulphate is less than 0.05 weight %, the removal rate of copper is lowered, and if the content of persulphate is more than 5 weight %, the corrosion on the copper surface is increased.

Further, by controlling the content of the oxidizer in the neutral pH region to be 0.1˜3 weight %, it is possible to minimize the surface detects of the copper layer. It is preferable that glycine having the high removal rate is used as the complexing agent. In order to maintain the lower etch rate and also increase the removal rate, if the zeolite is used as the abrasive and the contents of the glycine and oxidizer are maintained to be low, it is possible to considerably reduce the surface detects of the copper layer and the barrier layer without the anticorrosive agent. In case that the glycine is used in the neutral pH region, it is preferable that the content of glycine is 0.01˜0.7 weight %, more preferably, 0.05˜0.5 weight %. If the content is less than 0.01 weight %, the removal rate of the copper layer is lowered, and if the content is more than 0.7 weight %, the etch rate of the copper layer is increased and thus defect like the dishing is occurred.

The bulk copper polishing composition according to the present invention may further comprise one or more additives selected from an anticorrosive agent, a surfactant, aminoalcohol, a water-soluble polymer, an anti-foaming agent and a fungicide, and also further comprise abrasive particles having a mechanical polishing function.

The anticorrosive agent contained in the polishing slurry composition according to the present invention functions to restrict the corrosion of copper and thus stabilize the copper surface, thereby reducing the defects after the polishing process. The anticorrosive agent includes benzotriazole or tetrazole-based compounds. That is, one or more selected from a group of benzotriazole, 5-aminotetrazole, 1-alkyl-aminotetrazole, 5-hydroxy-tetrazole, 1-alkyl-5-hydroxy-tetrazole, tetrazole-5-thiol, imidazole and a mixture thereof may be used as the anticorrosive agent, and more preferably, benzotriazole is used. It is preferable that alkyl in the tetrazole-based compound is C1-C5 linear or branched alkyl. The content of the anticorrosive agent with respect to the entire weight of the polishing composition is preferably 0.0001˜0.5 weight % and more preferably, 0.0001˜0.05 weight %. If the content of the anticorrosive agent is more than 0.05 weight %, the removal rate of the copper layer is lowered and it exerts a bad influence on a cleaning process after the polishing process, and if the content of the anticorrosive agent is less than 0.0001 weight %, the removal rate is increased, but the dishing may be occurred due to the increase in the corrosiveness.

The surfactant contained in the polishing slurry composition comprises one or more selected from dodecylbenzenesulfonic acid, lauryloxysulfonic acid, ligninsulfonic acid, naphthalenesulfonic acid, dibutyl naphthalenesulfonic acid, laurylethersulfonic acid and salt thereof. The content of the surfactant with the entire weight of the polishing composition is preferably 0.001˜0.5 weight %, more preferably, 0.05˜0.5 weight %. It is more preferable that dodecylbenzenesulfonic acid or salt thereof having a structure of twelve carbon chains and sulfonate (SO₃⁻) and functioning to prevent the corrosion and perform lubricating operation is used, thereby increasing the removal rate and preventing the corrosion. If the content of the surfactant is less than 0.001 weight %, anti-corroding action is not performed sufficiently, and if content of the surfactant is more than 0.5 weight %, a large amount of foams is generated.

When using the surfactant, the polishing composition according to the present invention may further comprises the antifoaming agent. The antifoaming agent functions to restrict generation of the foams generated by using the surfactant, and its kind is not limited especially, and the content thereof can be properly controlled according to the content of the surfactant. The antifoaming agent can be classified into a silicon-based antifoaming agent and a non-silicon-based antifoaming agent. For example, the silicon-based antifoaming agent includes an antifoaming agent containing polydialkylsiloxane, and the non-silicon-based antifoaming agent includes an antifoaming agent containing polyalkyleneglycol. It is preferable that the alkyl in the polydialkylsiloxane and polyalkyleneglycol is C1-C5 linear or branched alkyl.

Further, the present invention may further comprise aminoalcohol in order to lower the removal rate of the barrier layer and improve dispersion stability of the slurry. Since the content of the aminoalcohol can be controlled, it is not necessary to especially limit the content. However, it is preferable that the content is 0.01˜1.0 weight %. If the content of the aminoalcohol is less than 0.01 weight %, a function of lowering the removal rate is deteriorated, and if the content of the aminoalcohol is more than 1.0 weight %, the dispersion stability is deteriorated. The aminoalcohol includes 2-amino-2-methyl-1-propanol (AMP), 3-amino-1-propanol, 2-amino-1-propanol, 1-amino-2-propanol, 1-amino-pentanol, 2-(2-aminoethylamino)ethanol, 2-dimethylamino-2-methyl-1-propanol, N,N-diethylethanolamine, monoethanolamine, diethanolamine, triethanolamine or a mixture thereof.

The polishing composition according to the present invention may further comprise water soluble polymer. The water soluble polymer functions to increase the removal rate, block the copper layer in a concave portion of a substrate to be polished, increase an removal rate of step height and thus finally reduce the dishing. The water soluble polymer includes polyethylene glycol, polyvinylalcohol, polyacrylic acid, polymethacrylic acid, polyacrylamide, polyvinylpyrrolidone, polyethylene oxide, as well as a material having natural polymer like hydroxyethyl cellulose and carboxymethyl cellulose as a constituent body. A copolymer comprising at least two or more different monomers like polyacrylic acid copolymer also can be used as the water soluble polymer. It is preferable that polyacrylic acid is used as the water soluble polymer, and the content of the water soluble polymer is 0.001˜2 weight % with respect to the entire weight of the polishing composition, more preferably, 0.02˜1 weight %. If the content of the water soluble polymer is less than 0.001 weight %, the dishing reduction effect is deteriorated, and if the content of the water soluble polymer is more than 2 weight %, the dispersion stability is deteriorated.

The polishing composition of the present invention may further comprise the fungicide so as to restrict microbial proliferation.

Further, the present invention may further comprise abrasive particles having a mechanical polishing function. Fumed silica, colloidal silica, alumina, ceria, organic polymer particles, or a mixture thereof may be used as the abrasive particles, and it is more preferable that the colloidal silica is used. Preferably, a size of the abrasive particle is 5˜2000 nm, more preferably, 10˜500 nm. Since the content of the abrasive particles can be controlled as occasion demands, it is not necessary to especially limit the content. However, it is preferable that the content is 0.01˜8.0 weight %, more preferably, 0.05˜3.0 weight %. If the content is less than 0.01 weight %, the mechanical polishing function is deteriorated, and if the content is more than 8.0 weight %, the dispersion stability is deteriorated, or the scratch is generated.

According to the bulk copper CMP composition of the present invention, in the acid pH region, there is a composition which comprises zeolite of 0.3˜5 weight %, citric acid of 0.05˜0.5 weight %, dodecylbenzenesulfonic acid or salt thereof of 0.05˜0.5 weight %, benzotriazole of 0.0001˜0.5 weight % and hydrogen peroxide of 3˜10 weight %, wherein the pH is 3˜6.5 and a secondary particle size of zeolite is 50˜300 nm, and in the basic pH region, there is a composition which comprises zeolite of 0.3˜5 weight %, citric acid of 0.05˜0.5 weight %, dodecylbenzenesulfonic acid or salt thereof of 0.05˜0.5 weight %, benzotriazole of 0.0001˜0.5 weight % and ammonium persulfate of 0.5˜3 weight %, wherein the pH is 8.5˜12 and a secondary particle size of zeolite is 50˜300 nm.

And in the neutral pH region, there is a composition which comprises zeolite of 0.3˜5 weight %, glycine of 0.05˜0.5 weight %, hydrogen peroxide of 0.1˜2 weight % and dodecylbenzenesulfonic acid or salt thereof of 0.001˜0.5 weight %, and wherein the pH is 6.5˜8.5 and a secondary particle size is 50˜300 nm, wherein the composition further comprises one or more selected from polyacrylic acid of 0.001˜2 weight % and benzotriazole of 0.0001˜0.5 weight %, and also further comprises aminoalcohol of 0.01˜1.0 weight %.

In addition, there is provided a method of fabricating a semiconductor, in which a semiconductor substrate including copper is polished by using a CMP composition according to the present invention.

[Best Model]

Practical and presently preferred embodiments of the present invention are illustrative.

However, it will be appreciated that those skilled in the art, on consideration of this disclosure, may make modifications and improvements within the spirit and scope of the present invention.

A copper wafer and a tantalum wafer in a polishing process are used as a test wafer which is deposited in a thickness of 10000 Å and 2000 Å by a PVD method, respectively. A thickness of the metal layer is calculated by measuring a sheet resistance using a four point probe manufactured by a changmin tech Company and then converting into the thickness value. After the copper wafer is immersed into a polishing slurry for 10 minutes at a room temperature and then cleaned, a change in the thickness is measured and thus a etch rate can be calculated. A corrosion level can be checked by observing a surface status using the naked eye or an optical microscope. The observed results are distinguished into a case that the surface state is good, a case that little corrosion is occurred and serious corrosion is generated. The case that the surface state is good is indicated as “◯”, the case that little corrosion is occurred is indicated as “Δ”, and serious corrosion is generated is indicated as “X”. The zeolite is pulverized by an attrition mill and then used. Further, a particle size of the zeolite described in each embodiment is an average value of secondary particle sizes of the zeolite. Nitric acid and potassium hydroxide are used as a pH controlling agent. In each embodiment, BTA is benzotriazole, DBS is dodecylbenzene sulfonic acid, and PAA is polyacrylic acid.

### Embodiment 1: Polishing Property According to Content of Citric Acid

Poli500 CE manufactured by G&P Technology Company is used as polishing equipment. In polishing conditions, A Table/Head speed is 30/30 rpm, a polishing pressure is 100 g/cm², a slurry supplying rate is 200 ml/min, and a polishing time is 60 seconds. And IC 1400 manufactured by Rohm and Haas Company is used as a polishing pad.

ZSM-5 type zeolite is pulverized by the attrition mill to have a size of 170 nm, and then a content of the zeolite is 1 weight %. After BTA of 0.08 weight %, DBS of 0.1 weight %, and hydrogen peroxide of 8 weight % are added, while a content of citric acid is changed to be respectively 0.15 weight %, 0.3 weight % and 0.60 weight %, and pH is maintained at 3.8. Then, a removal rate and an etch rate are evaluated.

TABLE 1

| | | Removal rate | Etch rate |
|---|---|---|---|
| Experiment | Citric acid | of Cu | of Cu |
| No. | (weight %) | (Å/min) | (Å/min) |
| 1-1 | 0.15 | 2133 | 4.5 |
| 1-2 | 0.30 | 3227 | 9.4 |
| 1-3 | 0.60 | 5253 | 232 |

As shown in Table 1, the removal rate and etch rate of a copper layer are measured according to the content of citric acid. It can be understood that the removal rate is increased according as the content of citric acid is increased. When the content of citric acid is 0.6 weight %, the etch rate is remarkably increased in comparison with when the content is 0.3 weight %. In the Table 1, it is preferable in an aspect of the etch rate that the content of citric acid is less than 0.6 weight %, more preferably, 0.5 weight % or less. Meanwhile, in case that the content of citric acid is more than 0.6 weight %, the composition can be used only when the etch rate is lowered by adding an anticorrosive agent.

### Embodiment 2: Polishing Property According to Content of Zeolite

The polishing composition comprises citric acid of 0.3 weight %, BTA of 0.08 weight %, DBS of 0.1 weight %, hydrogen peroxide of 8 weight %, and the pH is 3.9. The ZSM-5 type zeolite having a particle size of 170 nm is used, and the experiments are performed in the same conditions as in the embodiment 1 except that a content of the zeolite is changed to be respectively 1 weight % and 2 weight %.

TABLE 2

| | | Removal rate | Etch rate |
|---|---|---|---|
| Experiment | Zeolite | of Cu | of Cu |
| No. | (weight %) | (Å/min) | (Å/min) |
| 1-2 | 1 | 3227 | 9.4 |
| 2-1 | 2 | 4567 | 10.4 |

In the evaluated result of the removal rate of the copper layer according to the content of zeolite, as shown in Table 2, it can be understood that the removal rate is improved when the content of zeolite is increased from 1 weight % to 2 weight %, and the etch rate is hardly changed.

### Embodiment 3: Polishing Property According to Content of Hydrogen Peroxide

The polishing composition comprises ZSM-5 type zeolite of 2 weight %, which is pulverized to have a particle size of 170 nm, citric acid of 0.3 weight %, BTA of 0.08 weight %, and DBS of 0.1 weight %, while a content of the hydrogen peroxide is changed to be respectively 4 weight %, 6 weight % and 8 weight %. And then the evaluation is performed in the same conditions as in the embodiment 1 except that the pH is 3.9.

TABLE 3

| | | | Removal | | |
|---|---|---|---|---|---|
| | Hydrogen | | rate of | Etch rate | |
| Experiment | peroxide | | Cu | of Cu | Etched |
| No. | (weight %) | pH | (Å/min) | (Å/min) | surface |
| 3-1 | 4 | 3.9 | 3600 | 22 | Δ |
| 3-2 | 6 | 3.9 | 4006 | 13 | ◯ |
| 3-3 | 8 | 3.9 | 4567 | 10.4 | ◯ |

◯: not corroded(good),
Δ: a little corroded,
X: seriously corroded

In the evaluated result of the removal rate of the copper layer according to the content of hydrogen peroxide, as shown in Table 3, it can be understood that the removal rate of the copper layer is increased according as the content of hydrogen peroxide is increased, and the etch rate is reduced.

### EXAMPLE 4

### Polishing Property According to Content of Surfactant

The polishing composition comprises ZSM-5 type zeolite of 2 weight %, which is pulverized to have a particle size of 177 nm, citric acid of 0.3 weight %, BTA of 0.08 weight %, and hydrogen peroxide of 8 weight %, and the pH is maintained at 3.9, while a content of the DBS is changed to be respectively 0 weight %, 0.01 weight %, 0.1 weight % and 0.3 weight %. And then the evaluation is performed in the same conditions as in the embodiment 1.

TABLE 4

| | | | Removal | | |
|---|---|---|---|---|---|
| | | | rate of | Etch rate | |
| Experiment | DBS | | Cu | of Cu | Etched |
| No. | (weight %) | pH | (Å/min) | (Å/min) | surface |
| 4-1 | 0 | 3.9 | 1878 | 215 | X |
| 4-2 | 0.01 | 3.9 | 4930 | 195 | Δ |
| 4-3 | 0.1 | 3.9 | 4856 | 6.9 | ◯ |
| 4-4 | 0.3 | 3.9 | 3907 | 1 | ◯ |

As shown in Table 4, when the content of DBS is 0.01 weight %, the removal rate of the copper layer is largely improved. It can be understood that the removal rate of the copper layer is increased and the etch rate is reduced, when the content is more than 0.1 weight %, and also the addition of surfactant is contributed to improvement of the polishing and etching properties which are an important factor of the polishing composition.

### Embodiment 5: Polishing Property According to Content of BTA

The polishing composition comprises ZSM-5 type zeolite of 2 weight %, which is pulverized to have a particle size of 177 nm, citric acid of 0.3 weight %, DBS of 0.1 weight %, and hydrogen peroxide of 8 weight %, and the pH is maintained at 3.9, while a content of the BTA is changed to be respectively 0 weight %, 0.08 weight %, 0.1 weight % and 0.3 weight %. And then the evaluation is performed in the same conditions as in the embodiment 1.

TABLE 5

| | | | Removal | | |
|---|---|---|---|---|---|
| | | | rate of | Etch rate | |
| Experiment | BTA | | Cu | of Cu | Etched |
| No. | (weight %) | pH | (Å/min) | (Å/min) | surface |
| 5-1 | 0 | 3.9 | 5283 | 89 | X |
| 5-2 | 0.08 | 3.9 | 4664 | 5 | ◯ |
| 5-3 | 0.1 | 3.9 | 3891 | 1 | ◯ |
| 5-4 | 0.3 | 3.9 | 1515 | 1 | ◯ |

As shown in Table 5, it can be understood that the etch rate is sharply reduced, when the BTA is added.

### Embodiment 6: Polishing Property According to Change in pH

The polishing composition comprises ZSM-5 type zeolite of 2 weight %, which is pulverized to have a particle size of 177 nm, citric acid of 0.3 weight %, DBS of 0.1 weight %, BTA of 0.08 weight % and hydrogen peroxide of 8 weight %. Then, the evaluation is performed according to change of pH, and the other conditions are the same conditions as in the embodiment 1.

TABLE 6

| | | Removal rate | Etch rate | |
|---|---|---|---|---|
| Experiment | | of Cu | of Cu | Etched |
| No. | pH | (Å/min) | (Å/min) | surface |
| 6-1 | 3.6 | 1984 | 2.1 | ◯ |
| 6-2 | 3.9 | 4505 | 1.7 | ◯ |
| 6-3 | 4.5 | 2145 | 0.8 | ◯ |
| 6-4 | 5 | 1520 | 0.4 | ◯ |
| 6-5 | 9 | 36 | 0 | ◯ |

As shown in Table 5, it can be understood that the removal rate is the highest at the pH of 3.9, and the etch rate is low in all of the compositions of the embodiment.

### Embodiment 7: Basic Polishing Composition

In the embodiment, basic polishing compositions are prepared. That is, the polishing and etching properties are evaluated in a status that the polishing compositions have pH of 9.3 or 9.6. The polishing composition comprises ZSM-5 type zeolite of 2 weight %, which is pulverized to have a particle size of 177 nm, ammonium persulfate of 1 or 2 weight %, citric acid of 0.1, 0.3 and 0.5 weight %, BTA of 0.0005 weight %, DBS of 0.05, 0.1 and 0.2 weight %. And, the polishing conditions are the same conditions as in the embodiment 1.

TABLE 7

| | | | | | | Removal | Etch |
|---|---|---|---|---|---|---|---|
| Exper- | | | | | | rate of | rate |
| iment | | Ammonium | Citric | | | Cu | of Cu |
| No. | pH | persulfate | acid | zeolite | DBS | (Å/min) | (Å/min) |
| 7-1 | 9.3 | 1 | 0.1 | 1 | 0.05 | 4082 | 9 |
| 7-2 | 9.3 | 1 | 0.3 | 1 | 0.05 | 4561 | 2 |
| 7-3 | 9.3 | 1 | 0.5 | 1 | 0.05 | 4228 | 4 |
| 7-4 | 9.6 | 1 | 0.3 | 1 | 0.05 | 6925 | 1 |
| 7-5 | 9.3 | 2 | 0.3 | 1 | 0.05 | 6718 | 57 |
| 7-6 | 9.3 | 2 | 0.3 | 1 | 0.1 | 9202 | 26 |
| 7-7 | 9.3 | 1 | 0.3 | 2 | 0.1 | 6050 | 35 |
| 7-8 | 9.3 | 1 | 0.3 | 1 | 0.2 | 6404 | 19 |
| 7-9 | 9.3 | 2 | 0.3 | 0.5 | 0.2 | 9100 | 20 |

As shown in Table 7, it can be understood that the removal rate is increased when ammonium persulfate as an oxidizer is added. Particularly, the removal rate is increased when ammonium persulfate is increased from 1 weight % to 2 weight % and when the pH is increased from 9.3 to 9.6. However, the change of the removal rate according to the content of citric acid is relatively small.

### Embodiment 8: Polishing Property According to Kind of Abrasive

The polishing composition comprises citric acid of 0.3 weight %, DBS of 0.1 weight %, BTA of 0.08 weight %, hydrogen peroxide of 8 weight %, and the pH is maintained at the pH of 3.9, and then zeolite and other type abrasive are used. Colloidal silica manufactured by Ace High tech company and S-Chem Tech and fumed alumina (alu-3) manufacture by Degussa company are used. The polishing conditions are the same conditions as in the embodiment 1.

TABLE 8

| | | | Removal rate | Etch rate |
|---|---|---|---|---|
| Experiment | | | of Cu | of Cu |
| No. | Abrasive | Content | (Å/min) | (Å/min) |
| 8-1 | ZSM-5 zeolite | 2 | 4539 | 10.8 |
| 8-2 | Colloidal | 2 | 3152 | 198 |
| | silica(primary | | | |
| | particle size | | | |
| | of 45 nm) | | | |
| 8-3 | Colloidal | 2 | 3714 | 155 |
| | silica(primary | | | |
| | particle size | | | |
| | of 80 nm) | | | |
| 8-4 | Colloidal | 2 | 3778 | 168 |
| | silica(primary | | | |
| | particle size | | | |
| | of 30 nm) | | | |
| 8-5 | Fumed alumina | 2 | 2773 | 174 |

As shown in Table 8, in case that the polishing composition is prepared by ZSM-5 type zeolite, the removal rate is the fastest and the etch rate is the lowest, thereby obtaining excellent polishing property.

### Embodiment 9: Evaluation of Selectivity

The polishing composition comprises ZSM-5 type zeolite of 2 weight %, citric acid of 0.3 weight %, hydrogen peroxide of 8 weight %, DBS of 0.1 weight %, BTA of 0.08 weight %, and the pH is changed to be respectively 3.9 and 9.6, and the polishing evaluation of 8-inch Cu and Ta wafers is performed by using an Unipla 211 CMP equipment manufactured by Doosan DND company.

Polishing Condition in Acid pH Region

A slurry flow rate is 200 ml/min, a rotational speed of spindle is 120 rpm, a rotational speed of platen is 24 rpm, a wafer pressure is 2.4 psi, a retainer ring pressure is 6 psi, and a pad manufactured by Dong sung A&T company is used.

Polishing Condition in Basic pH Region

the slurry flow rate is 300 ml/min, the rotational speed of spindle is 120 rpm, the rotational speed of platen is 24 rpm, the wafer pressure is 4.3 psi, the retainer ring pressure is 6 psi, and the pad manufacture by Dong sung A&T company is used.

TABLE 9

| | zeolite | | | Removal | | Etch |
|---|---|---|---|---|---|---|
| Exper- | Secondary | | | rate of | | rate of |
| iment | particle | Content | | Cu | Selectivity | Cu |
| No. | size (nm) | (weight %) | pH | (Å/min) | (Cu/Ta) | (Å/min) |
| 9-1 | 140 | 2 | 3.9 | 8046 | 80 | 4 |
| 9-2 | 170 | 2 | 3.9 | 11146 | 111 | 8 |
| 9-3 | 120 | 1 | 9.6 | 12321 | 239 | 4 |

As shown in Table 9, the polishing composition according to the present invention has a high removal rate of the copper layer and a low etch rate of copper, and thus it is possible to restrict the corrosion and dishing. And also since the polishing composition has a high polishing selectivity of the copper layer, it has an excellent property which can be used as a bulk copper polishing composition.

### Embodiment 10: Polishing Property According to Kind of Complexing Agent in Neutral pH Region

Unipla 211 CMP equipment manufactured by Doosan DND company is used as the CMP equipment. In the polishing condition, the slurry flow rate is 200 ml/min, the rotational speed of spindle is 120 rpm, the rotational speed of platen is 24 rpm, the wafer pressure is 2.5 psi, and the polishing pad (ICI000 A2) manufactured by Rhom & Hass company is used. The ZSM-5 type zeolite is pulverized to having a secondary particle sized of 120 nm and then used as the abrasive.

The removal rate of the copper layer is evaluated, while the pH is maintained at 7.7 and the kind of complexing agent is changed.

TABLE 10

| | | | | | | | | Removal |
|---|---|---|---|---|---|---|---|---|
| | Complexing agent | | | | | | | rate of |
| Experiment | | Content | | Zeolite | H₂O₂ | DBS | PAA | Cu |
| No. | kind | (wt %) | pH | (wt %) | (wt %) | (wt %) | (wt %) | (Å/min) |
| 10-1 | Glycine | 0.5 | 7.7 | 1.5 | 3 | 0.005 | 0.3 | 4985 |
| 10-2 | Glycine | 0.5 | 7.7 | 1.5 | 2 | 0.005 | 0.3 | 4567 |
| 10-3 | Glycine | 0.5 | 7 | 1.5 | 2 | 0.005 | 0.3 | 3770 |
| 10-4 | Glycine | 0.5 | 8.5 | 1.5 | 2 | 0.005 | 0.3 | 4689 |
| 10-5 | Citric | 0.5 | 7.7 | 1.5 | 3 | 0.005 | 0.3 | 1148 |
| | acid | | | | | | | |
| 10-6 | Citric | 0.5 | 7.7 | 1.5 | 5 | 0.005 | 0.3 | 1503 |
| | acid | | | | | | | |
| 10-7 | Alanine | 0.5 | 7.7 | 1.5 | 2 | 0.005 | 0.3 | 2606 |
| 10-8 | Alanine | 0.5 | 7.7 | 1.5 | 3 | 0.005 | 0.3 | 2347 |
| 10-9 | BTTCA | 0.5 | 7.7 | 1.5 | 2 | 0.005 | 0.3 | 120 |
| 10-10 | QNA | 0.5 | 7.7 | 1.5 | 2 | 0.005 | 0.3 | 2049 |
| 10-11 | Tartaric | 0.5 | 7.7 | 1.5 | 2 | 0.005 | 0.3 | 834 |
| | acid | | | | | | | |

*BTTCA: Benzenetetracarboxylic acid
*QNA: quinolinic acid

As shown in Table 10, the polishing evaluation is performed while the complexing agent is changed. In case that glycine is used as the complexing agent in the neutral pH region, the removal rate is the highest.

Further, there is a tendency that the removal rate is more increased at the pH of 7.7 than the pH of 7, and the surface is corroded at the pH of 6.5 or less when performing the etching process. And similar removal rates are shown at the pH of 8.5, but if the pH is more than 8.5, stability of hydrogen peroxide is relatively deteriorated and thus there is trouble in polishing reproductivity. Therefore, it is preferable that the pH is controlled within an extent of 6.5˜8.5.

### Embodiment 11: Polishing Property According to Content of Glycine

As shown in Table 11 to be described below, the copper polishing property is evaluated while the content of glycine is changed.

TABLE 11

| | Content | | | | | | Removal | Etch |
|---|---|---|---|---|---|---|---|---|
| | of | | | | | | rate of | Rate of |
| Experiment | glycine | | Zeolite | H₂O₂ | DBS | PAA | Cu | Cu |
| No. | (wt %) | pH | (wt %) | (wt %) | (wt %) | (wt %) | (Å/min) | (Å/min) |
| 11-1 | 0.3 | 7.7 | 1.5 | 2 | 0.005 | 0.3 | 3225 | 48.6 |
| 11-2 | 0.4 | 7.7 | 1.5 | 2 | 0.005 | 0.3 | 4170 | 32.3 |
| 11-3 | 0.5 | 7.7 | 1.5 | 2 | 0.005 | 0.3 | 4567 | 18.6 |
| 11-4 | 0.7 | 7.7 | 1.5 | 2 | 0.005 | 0.3 | 5250 | 263 |
| 11-5 | 1 | 7.7 | 1.5 | 2 | 0.005 | 0.3 | 7043 | 307 |

As described above, the content of glycine is changed. It can be understood that the removal rate is increased according as the content of glycine is increased. When the content of glycine is more than 0.7 weight %, a corrosion rate is high, and thus it is preferable that the content of glycine is 0.7 weight % or less.

### Embodiment 12: Polishing Property According to Content of Hydrogen Peroxide

As shown in Table 12 to be described below, the copper polishing property is evaluated while the content of glycine is changed. The surface state after the polishing process is observed by the naked eye or an optical microscope.

TABLE 12

| | | | | | | | | | Etch |
|---|---|---|---|---|---|---|---|---|---|
| | Content | | | | | | Removal | | Rate |
| | of | | | | | | rate of | | of |
| Experiment | glycine | | Zeolite | H₂O₂ | DBS | PAA | Cu | Surface | Cu |
| No. | (wt %) | pH | (wt %) | (wt %) | (wt %) | (wt %) | (Å/min) | state | (Å/min) |
| 12-1 | 0.5 | 7.7 | 1.5 | 0.5 | 0.005 | 0.3 | 5824 | ◯ | 49.6 |
| 12-2 | 0.5 | 7.7 | 1.5 | 1 | 0.005 | 0.3 | 6711 | ◯ | 2.4 |
| 12-3 | 0.5 | 7.7 | 1.5 | 2 | 0.005 | 0.3 | 4567 | Δ | 18.6 |
| 12-4 | 0.5 | 7.7 | 1.5 | 3 | 0.005 | 0.3 | 4331 | X | 178 |
| 12-5 | 0.5 | 7.7 | 0.5 | 1 | 0.005 | 0.3 | 4810 | ◯ | 3.26 |

As result of the change in the content of hydrogen peroxide, the removal rate of the copper layer is the highest, when the content of hydrogen peroxide is 1 weight %. Further, the etch rate is also lowered. It is possible to reduce the etch rate when BTA as a protective layer forming agent is not used in the neutral pH region and also when a ratio of oxidizer/organic acid is low.

### Embodiment 13: Polishing Property According to Addition of BTA

In order to evaluate the copper polishing property according to addition of BTA and content thereof, the slurry composition is changed as shown in Table 13 to be described below.

TABLE 13

| | Content | | | | | | | Removal | Etch |
|---|---|---|---|---|---|---|---|---|---|
| | of | | | | | | | rate | rate |
| Experiment | glycine | | | Zeolite | H₂O₂ | DBS | Surface | of Cu | of Cu |
| No. | (wt %) | BTA | pH | (wt %) | (wt %) | (wt %) | state | (Å/min) | (Å/min) |
| 13-1 | 0.5 | 0 | 7.7 | 1 | 1 | 0.05 | ◯ | 5286 | 19 |
| 13-2 | 0.5 | 0.001 | 7.7 | 1 | 1 | 0.05 | ◯ | 3394 | 3 |
| 13-3 | 0.5 | 0.003 | 7.7 | 1 | 1 | 0.05 | ◯ | 2688 | 5 |

As shown in Table 13, the removal rate is lowered due to the addition of BTA, but the corrosion rate is further lowered. The surface state is not deteriorated.

### INDUSTRIAL APPLICABILITY

The polishing composition according to the present invention has a high removal rate of the copper layer and a low etch rate of copper, and thus it is possible to restrict the corrosion and dishing. And also since the polishing composition has a high polishing selectivity of the copper layer, it has an excellent property which can be used as a bulk copper polishing composition.

Those skilled in the art will appreciate that the conceptions and specific embodiments disclosed in the foregoing description may be readily utilized as a basis for modifying or designing other embodiments for carrying out the same purposes of the present invention. Those skilled in the art will also appreciate that such equivalent embodiments do not depart from the spirit and scope of the invention as set forth in the appended claims.

1. A chemical mechanical polishing composition for polishing a copper substrate, said polishing composition comprising: zeolite, an oxidizer, and a complexing agent, wherein a content of the complexing agent is 0.01˜0.8 weight % with respect to an entire weight of the polishing composition.

2. The chemical mechanical polishing composition as set forth in claim 1, wherein the zeolite is 0.1˜7 weight % with respect to the entire weight of the polishing composition, and the oxidizer is 0.01˜15 weight %.

3. The chemical mechanical polishing composition as set forth in claim 2, wherein the complexing agent is one or more selected from citric acid, malonic acid, adipic acid, succinic acid, oxalic acid, gluconic acid, tartaric acid, malic acid, diethylmalonic acid, acetic acid, mercaptosuccinic acid, benzenetetracarboxylic acid, quinolinic acid, glycine, alanine, valine, aspartic acid, glutamic acid, and arginine.

4. The chemical mechanical polishing composition as set forth in claim 1, wherein the complexing agent is 0.05˜0.5 weight % with respect to the entire weight of the polishing composition.

5. The chemical mechanical polishing composition as set forth in claim 3, wherein the complexing agent is citric acid of 0.05˜0.5 weight % with respect to the entire weight of the polishing composition.

6. The chemical mechanical polishing composition as set forth in claim 2, wherein the zeolite has a secondary average particle size of 10˜1000 nm.

7. The chemical mechanical polishing composition as set forth in claim 6, wherein the zeolite is selected from an X type, a Y type, a 4A type and a ZSM-5 type.

8. The chemical mechanical polishing composition as set forth in claim 2, wherein pH of the composition is 3˜12.

9. The chemical mechanical polishing composition as set forth in claim 8, wherein the oxidizer is hydrogen peroxide of 1˜12 weight % in the pH of 3˜6.5.

10. The chemical mechanical polishing composition as set forth in claim 8, wherein the oxidizer is persulphate of 0.05˜5 weight % in the pH of 8.5˜12.

11. The chemical mechanical polishing composition as set forth in claim 8, wherein the pH is 6.5˜8.5.

12. The chemical mechanical polishing composition as set forth in claim 11, further comprising glycine of 0.01˜0.7 weight % with respect to the entire weight of the polishing composition as the complexing agent.

13. The chemical mechanical polishing composition as set forth in claim 12, further comprising hydrogen peroxide of 0.1˜3 weight % with respect to the entire weight of the polishing composition as the oxidizer.

14. The chemical mechanical polishing composition as set forth in claim 8, wherein the pH is controlled by a pH controlling agent selected from potassium hydroxide, nitric acid, tetramethylammonium hydroxide (TMAH), ammonium hydroxide (NH₄OH), and morpholine.

15. The chemical mechanical polishing composition as set forth in claim 1, wherein the polishing composition further comprises one or more selected from an anticorrosive agent, a surfactant, aminoalcohol, a water-soluble polymer, an anti-foaming agent and a fungicide.

16. The chemical mechanical polishing composition as set forth in claim 15, wherein the anticorrosive agent is one or more selected from a group of benzotriazole, 5-aminotetrazole, 1-alkyl-aminotetrazole, 5-hydroxy-tetrazole, 1-alkyl-5-hydroxy-tetrazole, tetrazole-5-thiol, imidazole and a mixture thereof and a content of the anticorrosive agent is 0.0001˜0.5 weight % with respect to the entire weight of the composition.

17. The chemical mechanical polishing composition as set forth in claim 15, wherein the surfactant is one or more selected from dodecylbenzenesuifonic acid, lauryloxysulfonic acid, ligninsulfonic acid, naphthalenesulfonic acid, dibutyl naphthalenesulfonic acid, laurylethersulfonic acid and salt thereof and a content of the surfactant with the entire weight of the polishing composition is 0.001˜0.5 weight %.

18. The chemical mechanical polishing composition as set forth in claim 15, wherein the antifoaming agent is one or more selected from polyalkyleneglycol-based compounds and polydialkylsiloxane-based compounds.

19. The chemical mechanical polishing composition as set forth in claim 15, wherein the aminoalcohol is selected from a group of 2-amino-2-methyl-1-propanol (AMP), 3-amino-1-propanol, 2-amino-1-propanol, 1-amino-2-propanol, 1-amino-pentanol, 2-(2-aminoethylamino)ethanol, 2-dimethylamino-2-methyl-1-propanol, N,N-diethylethanolamine, monoethanolamine, diethanolamine, triethanolamine and a mixture thereof, and a content thereof is 0.01˜1 weight % with respect to the entire weight of the polishing composition.

20. The chemical mechanical polishing composition as set forth in claim 15, wherein the water soluble polymer is selected from a group of carhoxymethyl cellulose, hydroxyethyl cellulose, polyethylene glycol, polyvinylalcohol, polyacrylic acid, polymethacrylic acid, polyacrylamide, polyvinylpyrrolidone, polyethylene oxide and a mixture thereof and a content thereof is 0.001˜2 weight % with respect to the entire weight of the polishing composition.

21. The chemical mechanical polishing composition as set forth in claim 15, further comprising abrasive particles selected from fumed silica, colloidal silica, alumina, ceria, organic polymer particles, and a mixture thereof, and a content thereof is 0.01˜8 weight % with respect to the entire weight of the polishing composition.

22. The chemical mechanical polishing composition as set forth in claim 15, wherein the polishing composition comprises zeolite of 0.3˜5 weight %, citric acid of 0.05˜0.5 weight %, dodecylbenzene sulfonic acid or salt thereof of 0.05˜0.5 weight %, benzotriazole of 0.0001˜0.5 weight %, and hydrogen peroxide of 3˜10 weight %, and the ph is 3˜6.5, and a secondary particle size of the zeolite is 50˜300 nm.

23. The chemical mechanical polishing composition as set forth in claim 15, wherein the polishing composition comprises zeolite of 0.3˜5 weight %, citric acid of 0.05˜0.5 weight %, dodecylbenzene sulfonic acid or salt thereof of 0.05˜0.5 weight %, benzotriazole of 0.0001˜0.5 weight %, and ammonium persulfate of 0.5˜3 weight %, and the ph is 8.5˜12, and a secondary particle size of the zeolite is 50˜300 nm.

24. The chemical mechanical polishing composition as set forth in claim 15, wherein the polishing composition comprises zeolite of 0.3˜5 weight %, glycine of 0.05˜0.5 weight %, hydrogen peroxide of 0.1˜2 weight %, dodecylbenzene sulfonic acid or salt thereof of 0.001˜0.5 weight %, polyacrylic acid of 0.001˜2 weight % and benzotriazole of 0.0001˜0.5 weight %, and the pH is 6.5˜8.5, and a secondary particle size of the zeolite is 50˜300 nm.

25. A method of fabricating a semiconductor device, in which a copper or substrate is polished using the chemical mechanical polishing composition as set forth in claim 1.
